(19) United States
(12) Patent Application Publication
(10) Pub. No.: US 2022/0305559 A1
(43) Pub. Date: Sep. 29, 2022

(54) LIQUID METAL EJECTION PRINTING

(71) Applicant: MASSACHUSETTS INSTITUTE OF TECHNOLOGY, Cambridge, MA (US)

(72) Inventors: Anastasios HART, Wabon, MA (US); Ulrich MUECKE, Cambridge, MA (US); Henry MERROW, Cambridge, MA (US); Justin BEROZ, Cambridge, MA (US); Caroline JORDAN, Delray Beach, FL (US); Kaihao ZHANG, Cambridge, MA (US)

(73) Assignee: MASSACHUSETTS INSTITUTE OF TECHNOLOGY, Cambridge, MA (US)

(21) Appl. No.: 17/616,882

(22) PCT Filed: Jun. 7, 2020
(86) PCT No.: PCT/US2020/036525

§ 371 Date: Dec. 6, 2021

Related U.S. Application Data
(60) Provisional application No. 62/858,944, filed on Jun. 7, 2019.

(51) Int. Cl. B22F 10/22; B33Y 10/00; B33Y 30/00; B33Y 40/00; B33Y 50/00; B22F 10/80; B22F 12/90; B22F 12/70; B22F 12/50

(52) U.S. Cl. CPC B22F 10/22; B33Y 10/00; B33Y 30/00; B33Y 40/00; B33Y 50/00; B22F 10/80; B22F 12/90; B22F 12/70; B22F 12/50

(57) ABSTRACT

A molten droplet printing system and method can provide molten droplets without surface contact at the time of generation.

### CLAIM OF PRIORITY

This application claims priority to U.S. Provisional Patent Application No. 62/858,944, filed Jun. 7, 2019, which is incorporated by reference in its entirety.

### FIELD OF THE INVENTION

The invention relates to generating molten droplets from a moving feedstock.

### BACKGROUND

Traditional printing methods can be limited by the material being printed. Moreover, three-dimensional printing techniques can lead to inaccurate distributions of solid materials on a substrate due to physical limitations of the printing method.

### SUMMARY

In one aspect, a method of generating individual molten droplets from a feed material. The method can include providing a feed material from a feed mechanism, and directing an energy source at or near an end of the feed material to form a liquified region of the feed material to make individual molten droplets. The method can include feeding the feed material at a rate sufficient to break the liquified region into individual droplets. The method can include altering the trajectory of the single droplet with a deflector. The method can include positioning droplets to impinge a target area of a substrate.

In another aspect, a device can include a feed mechanism that advances a feed material at a controlled speed or maintains a desired position of an end of the feed material, an alignment mechanism that determines trajectory and position of the feed material, and an energy source directed toward the end of the feed material to generate molten droplets. The device can include a deflector to modify the trajectory of the molten droplets.

In another aspect, a device can include a printing unit including a feed material feeder, an energy source directed at or near a tip of a feed material passing through the feed material feeder to generate a molten droplet that exits the printing unit, and a stage opposite the printing unit that receives the molten metal droplet to build a part or create a pattern. The feed material can be a wire or ribbon. The feed material can be a metal, an alloy, a composite, a plastic, a rubber, a ceramic, a glass or other material. Preferably, the feed material can be a metal wire.

In another aspect, a method of manufacturing a part can include generating a continuous stream of molten droplets from a feed material without physically contacting a tip of the feed material, while applying energy from an energy source, and depositing the molten droplet on a surface to form a pattern or part. The method can include supplying the feed material at a rate sufficient to break up a molten column of the feed material into a stream of individual droplets. The molten droplet can solidify once delivered to the surface. The solidification can be delayed by applying energy at the time of impact or bonding with the surface can be improved by applying energy at the time of impact.

In another aspect, a method of fabricating a metallic feature on a surface can include generating individual molten droplets, as described herein. The molten droplets can travel through a fluid medium after detaching from the feed material and prior to impacting the surface.

In another aspect, a method of forming a three-dimensional object can include generating individual molten droplets, as described herein. The molten droplets can travel through a fluid medium after detaching from the feed material and prior to impacting a surface to form a portion of the three-dimensional object.

In certain circumstances, the method can include applying multiple energy sources to the moving feed material, so as to control the temperature of the feed material along its length and influence the formation of droplets.

In certain circumstances, the method can include generating a single droplet traveling with a trajectory away from the feed mechanism.

In certain circumstances, sequentially produced molten droplets can be selected to be uniform in size or different in size.

In certain circumstances, the molten droplets can be generated in a controlled environment.

In certain circumstances, the method can include guiding the feed material through an alignment mechanism immediately before directing the energy source to the end of the feed material.

In certain circumstances, sequentially produced molten droplets can have a diameter that is larger than, equal to, or smaller than a diameter of the feed material.

In certain circumstances, the part or pattern can include a metal, ceramic or polymer.

In certain circumstances, the energy source can include an electromagnetic source, a plasma source, an electron beam source, a joule heating source, or an induction source, for example, a laser.

In certain circumstances, the energy source can be constant, modulated, or pulsed, or combinations thereof.

In certain circumstances, the device or method can include at least one droplet deflector in the flight path of the droplet. The deflector can be near an end of the feed material. The deflector can be an electric field, a magnetic field, a vapor propulsion wave or a plasma shock wave.

In certain circumstances, the deflector can include a trajectory modification by electric field deflection, magnetic field deflection, plasma shock wave deflection, vapor propulsion deflection, acoustic or acoustophoretic deflection, gas flow deflection, mechanical deflection, or a combination thereof. For example, the deflector can include a deflection surface. The deflection surface can include a dense or porous surface optionally including a liquid. The deflection surface can include a ceramic, a metal, a polymer or a composite fibrous nanostructure. The deflection surface can include cooling channels and can be flat or curved. The method can include controlling a temperature of the deflection surface.

In certain circumstances, the feed material can be a wire or ribbon. The feed material can include a metal, an alloy, a plastic, a rubber, a ceramic, or a glass. For example, the feed material can be a metal wire. The metal wire can include platinum, gold, silver, copper, palladium, nickel, cobalt or stainless steel. The feed material can include Sc, Ti, V, Cr, Mn, Fe, Co, Ni, Cu, Zn, Y, Zr, Nb, Mo, Ru, Rh, Pd, Ag, Cd, Hf, Ta, W, Ir, Pt, Au, Al, Ga, In, Sn, Pb, As, Sb, Bi, or S. For example, the feed material can be stainless steel, CoCr.

In certain circumstances, the device or method can include a second printing unit, for example, an inkjet printhead.

In certain circumstances, the device can include a three-axis, four-axis, five axis or six-axis control stage. Similarly this number of degrees of freedom may be controlled between the printing unit and the stage.

In certain circumstances, the stage can include a temperature controller.

In certain circumstances, the device or method can include an optical sensor to determine the position or trajectory of the feed material or one or more of the molten droplets. For example, the device or method can include a vision system oriented to view at least one of the stage, the printing unit, or a flight path of the molten droplet.

In certain circumstances, the energy source can include a photonic source, for example, a laser, directing light energy at the tip of the wire.

In certain circumstances, the device can include a second energy source, the second energy source generates heat at the stage or building part to facilitate building the part, for example, by preheating the wire to elevated temperature below material's melting point, by generating a molten surface on the part, by slowing the rate of solidification of the molten droplet, by sintering a portion of the part, or by annealing a portion of the part. The portion of the part can be a small section of the part or the entire part.

In certain circumstances, the wire feed can include a mechanism capable of moving the wire at a speed of 0.001 to 20 m/s.

In certain circumstances, the device can also include a vision system oriented to view the stage. The vision system can also be oriented to view one or more of the printing unit, and space between the printing unit and the stage. For example, the vision system can be oriented to view at least one of the stage, the printing unit, or a flight path of the molten droplet.

In certain circumstances, the printing unit includes a deflector in a flight path of the molten droplet that directs the molten droplet to the stage.

In certain circumstances, the molten droplet can solidify once delivered to the surface.

In certain circumstances, the method can include applying a material to the stage from a second printing unit.

Other aspects, embodiments, and features will be apparent from the following description, the drawings, and the claims.

### BRIEF DESCRIPTION OF THE DRAWINGS

FIG. 1 depicts a schematic of a device.

FIG. 2A depicts a schematic of RP-breakup of a wire heated by a laser beam.

FIG. 2B depicts a schematic of droplet deposition.

FIGS. 3A-3B depict images of droplet formation.

FIG. 4 depicts the influence of laser power, which affects a temperature gradient across the cross section of the wire; small temperature gradients result in incomplete melting, while large temperature gradients result in individual droplet generation.

FIGS. 5A-5F depict simulation results for droplet generation by constant laser power and wire speed.

FIGS. 6A-6D depict simulation results for droplet generation by duty-cycled laser power and constant wire speed.

FIG. 7A depicts deflection of droplet.

FIG. 7B depicts deflection of droplet.

FIG. 8A depicts droplet deflection.

FIG. 8B depicts droplet deposition.

FIG. 9 depicts schematic of droplet deflection.

FIG. 10 depicts images of droplet formation and displacement.

FIGS. 11A-11B depict embodiments of the wire alignment mechanism.

FIGS. 12A-12D depict embodiments for preheating.

FIG. 13 depicts a schematic of generating a force on droplet.

FIGS. 14A-14B shows a schematic of printing molten material droplets, exemplarily molten metal droplets from a metal wire feed.

FIGS. 15A-15B depict embodiments of a system.

FIG. 16 depict components for wire feed machine, including wire path through the apparatus.

FIGS. 17A-17B depict a physical embodiment of v-groove wire alignment mechanism.

### DETAILED DESCRIPTION

On-demand production, especially for parts with complex geometries and/or high-value material requirements, would be significant to many industries. Additive manufacturing (AM) processes broadly aim to enable this; however, state-of-the-art methods cannot achieve the dimensional resolution and surface finish required for precision applications such as dental implants and jewelry, unless extensive manual post-processing is applied. Production of metal components with customized and/or complex geometries is a longstanding manufacturing challenge. Current processes (including additive methods) can be highly labor intensive for small volumes of precision components or can require high capital investment for large volumes. For example, dental laboratories and jewelry making exemplify markets that produce products primarily of this type (small, detail-oriented and individually tailored and/or designed). A key value proposition in advancing the approach to making products in these technology areas relates to automating customized production. Both exemplary industries face similar challenges in producing customized items for individual clients and delivery of value to the customer can be highly time-sensitive and design-driven.

Three main methods are used today for metal 3D printing and additive manufacturing: powder bed fusion where a part is built from successive layers of powder molten by a laser or electron beam, direct energy deposition where material is build up by feeding a wire into a molten pool of metal created by a laser beam; and binder jetting where parts are made by ink jetting a binder fluid onto successive layers of powder followed by de-powdering and sintering.

Additionally, metal patterns or 3D structures can be formed by depositing a liquid molten metal directly onto a substrate. Known methods to eject droplets from reservoirs of molten metal through a small nozzle have proven challenging because of the corrosive nature of molten metals, thermal management issues, the inability to create molten droplets with varying temperature, and nozzle clogging due to oxide formation.

Molten metal printing from a feed material, such as a ribbon or a wire, as described here, advances metal printing technology with unexpected advantages. The system and method of molten metal printing from a wire consists of a process to generate a stream of metal droplets and optionally a way to modify the droplet flight path that enables printing of 2D patterns or 3D structures directly from molten material. Advantageously, the molten material does not come into contact with a crucible material or a nozzle, which reduces the likelihood of creating contamination and increases the lifetime of the printing unit by reducing wear and tear.

Moreover, the approach of generating molten metal from a wire can allow the temperature of each droplet to be controlled individually. In certain circumstances, individual droplet temperature control can be independent of droplet generation mechanism. Temperature control can be used with any drop generation mechanism. Generating and depositing individual droplets and controlling the temperature of each drop by heating during droplet formation or during flight can improve pattern or part accuracy and metallurgical properties compared to state-of-the-art technologies.

As described herein, exemplifying a wire as a feedstock or feed material, a method to generate individual molten droplets from a wire feedstock can include a wire feed mechanism, and liquefying the feed material with an energy source directed at or near an end of the feed material. The wire may be fed fast enough to break the liquefied region into individual droplets. In other circumstances, the wire may be heated to generate a single droplet travelling with a trajectory away from the wire. At least one deflector can be used to affect the speed and direction of the droplet in the vicinity of the end of the wire. The deflector can be located within a few centimeters or a few millimeters of the end of the wire or the target surface.

As described herein, a device to repeatedly generate molten droplets from a wire feedstock with controlled velocity and position can include a wire feed mechanism that advances a wire at a controlled speed and/or maintains a desired position of free end. The device can include a wire alignment mechanism that determines trajectory and position of the wire, both with respect to an absolute coordinate system and in relation to the energy source. The device can also include an energy source applied at or near the tip of the wire to generate molten droplets.

Sequentially produced droplets may be uniform in size, or different in size; may be larger, equal, or smaller than wire diameter. The details can be method specific. For example, the energy source can be modulated for each individual segment of the wire that ultimately breaks up into a droplet. This may produce individual droplets wherein the size and temperature of each depends on the particular modulation of the energy source. The energy source modulation may also be a duty cycle, for example a repeating on-off sequence; this periodic heating may create a spatially periodic distribution of temperature and surface tension along the liquefied portion of the wire, which influences the subsequent breakup into droplets. Alternatively, a constant energy source and feed rate may exhibit a multi-mode capillary instability, resulting in a periodic sequence of droplets (e.g., large-small-large-small- . . . ). A deflector may then, for instance, selectively deflect only the “small” droplets to a target substrate; the larger ones sent to a waste collection bin.

In another example, the amount and rate of heating, and location of heating relative to the end of the feed wire, can determine the size of the droplet that is deflected away.

The energy source can include one or more of the following: an electromagnetic source, a plasma source, an electron beam source, a joule heating source, an induction source, a convective source or a conductive source. The energy output can be modulated or pulsed or both. Each individual droplet can be heated to a different temperature. For example, the energy source can include a laser. The duration and intensity of exposure of each droplet to the energy source can be controlled so as to achieve a desired droplet temperature. In certain circumstances, the duration and intensity can be modulated for each droplet.

The feed material may be any cross section geometry. For example, the feed material can be a “wire”, in which perpendicular cross-section dimensions are substantially similar in size. In another example, the feed material can be a “ribbon”, in which perpendicular cross-section dimensions can be substantially different in size.

The feed material can include any solid material which is liquefied by the energy source, such as a metal, a metal alloy, a plastic, a rubber, a ceramic, a composite or a glass.

In certain circumstances, the feed material can be pre-heated by an additional energy source up to, but not over, the melting temperature.

The droplet trajectory can be modified with a deflector. The deflector can be a solid surface, oriented so that the droplet bounces off of it travelling in a desired direction. For example, the deflector can be actuated to change its orientation, and thereby the bounce direction, individually for each droplet. The deflection surface may be flat or curved.

The temperature of the deflection surface can be controlled.

The deflection surface can include a dense or porous surface optionally including a fluid; The fluid may be replenishable or circulating, for example, through cooling chambers or cooling channels.

The texture of the surface can be smooth or rough. For example, the roughness length scale can be small compared to the droplet length scale.

The deflector can be an electric or magnetic field subject on the droplet to impart a force in a desired direction. For example, a gradient electric field may deflect an uncharged droplet. In another example, a charged droplet may be deflected by an electric or magnetic field (according to the Lorentz force).

In certain circumstances, the deflector may be vapor propulsion or a plasma shock wave by superheating the droplet on one side. This can create a vapor plume that imparts momentum on the droplet.

In general, the deflector may modify the droplets trajectory by: electrostatic deflection, plasma shock wave deflection, vapor propulsion deflection, acoustic or acoustophoretic deflection, drag deflection, mechanical deflection, or a combination thereof.

Another important aspect of the device in method can involve delivery of the feed material to the energy source. In certain circumstances, alignment of the feed material via an alignment mechanism can utilize a mechanical constraint transverse to the wire feed direction. This can be accomplished by a rigid planar or curved surface, for example, a v-groove). Other factors that can influence the alignment of the feed material can include the bending stiffness of the feed material, inertia or centripetal acceleration of the feed material, or electric or magnetic fields to impart controlled forces on the feed material. The electric or magnetic fields can require a closed loop control system to sense the feed material position and change the strength of the field to maintain the feed material's position.

The wire may be aligned to intersect an energy source, for example, a laser.

Once the molten droplet is formed, the droplet may be directed towards a target surface in order to print a desired pattern or part. The target surface may be an arbitrarily large planar or contoured surface. The target surface may be fixed to a multi-degree of freedom stage, which may be actuated to change its position or orientation with respect to the incoming droplet. The target surface may be a metal, ceramic, polymer, glass. The molten droplet may solidify once delivered to the surface.

The droplets can be combined at the target to form a pattern or part. The pattern or prat can be formed of one or more materials.

A 2D pattern or 3D part may be built droplet-by-droplet.

In order to build a pattern or part, the thermal state of the particle and target substrate upon impact may be controlled. The particle temperature can be determined by the heating method described above. A portion of the target surface, pattern or part can be laser heated, softened, or melted before the impact of the molten droplet.

In certain circumstances, a second print unit may be included to print a multi-material part. The second printing unit may be an additional wire-fed droplet generator or an inkjet printhead.

The droplet generation device and target substrate can be housed inside an enclosure with environmental control. This configuration can allow the temperature of deposition to be controlled with heaters/coolers, and temperature sensors. The gas composition in the housing can be controlled via flow inlet/outlet ports with flow sensors or chemical sensors inside the enclosure. The gas composition can include air, an inert gas, a reducing gas, water vapor, or combination/percentage thereof. The gas pressure in the housing can be controlled via flow pumps and a pressure sensor. The enclosure can be maintained under reduced pressure, atmospheric pressure, or elevated pressure.

The device can include a vision system oriented to view at least one of the stage, the printing unit, or a flight path of the molten droplet(s). The vision system can provide feedback during the building of a pattern or part.

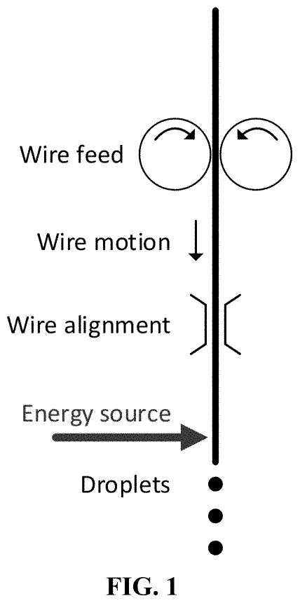

Referring to FIG. 1, a schematic of device to repeatedly generate droplets from a wire feedstock shows some key components can be a wire stock, wire feeder, alignment mechanism, energy source. The device can include deflector.

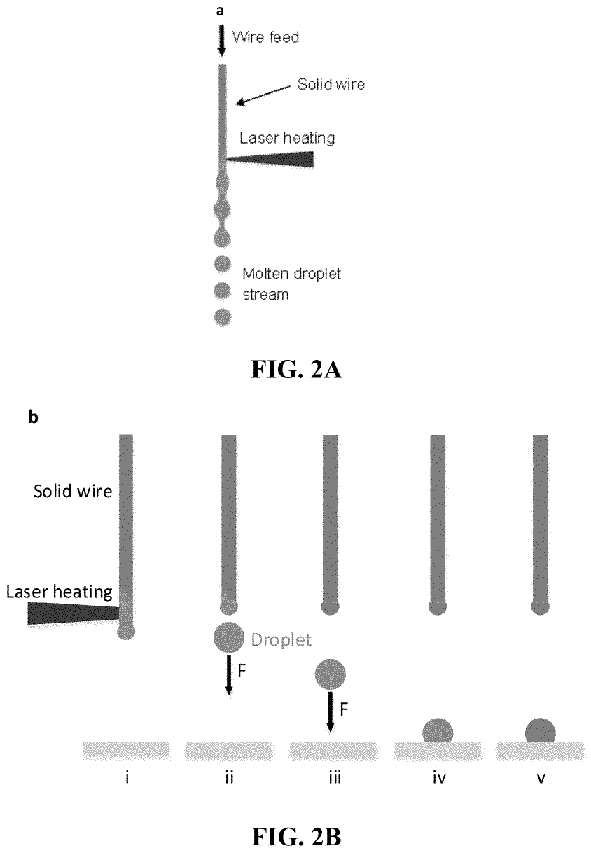

Referring to FIGS. 2A-2B, examples of droplet generation methods can include a continuous stream (FIG. 2A) or discrete droplet generation followed by deflection by an applied force (FIG. 2B).

The system and methods described here can have one or more of the following advantages or features.
1. Generation of a continuous stream of liquid metal droplets by melting a wire (for example, as a method and independent of anything else)
2. Adjusting the temperature of each individual droplet either during the generation of the stream or in flight (for example, generalized for all molten droplet processes and independent of the method of droplet generation and independent of anything else)
3. Modification of the trajectory of a stream of droplets by deflecting it from a surface (for example, generalized for all molten droplet processes and independent of the method of droplet generation or anything else)
4. Improving the adhesion/wetting/coalescence of a liquid molten droplet impinging on a surface by pre-heating/pre-melting the surface immediately before the droplet impact (for example, generalized for all molten droplet processes and independent of the method of droplet generation or trajectory modification or anything else)
5. Generating a liquid metal droplet on-demand by heating the tip of a wire with a laser beam and subsequently exerting a force on the droplet to propel it towards a substrate (for example, independent of anything else)
6. Generating a weakly bonded layer of particles to facilitate separation in post-processing by using a sufficiently small temperature difference between the molten droplet and the substrate (for example, generalized for all molten droplet processes independent of the method of droplet generation and trajectory modification or anything else)
7. A printer making a part utilizing various combinations of the above.

In an exemplary embodiment, a metal wire can be fed through a laser beam and subsequently melts. At sufficiently high wire velocities and appropriate laser energy input, the molten column formed by the wire breaks up into a stream of individual droplets that is then directed towards a deflecting surface mounted on a galvanometer or other rotatable element. The position of droplet landing on the substrate can be controlled by the angle of the deflecting surface, and therefore a pattern of metal droplets or a 3D part is formed on a substrate by deposition of a plurality of droplets with position control.

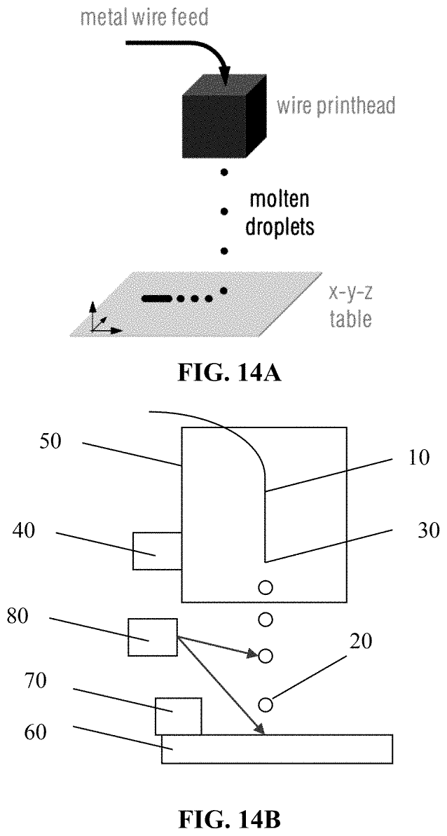

For example, FIGS. 14-14B show a schematic of printing molten material droplets, exemplarily molten metal droplets from a metal wire feed. In particular, feed material 10 generates molten metal droplet 20 when tip 30 of feed material 10 is heated by energy source 40 in printing unit 50. Molten metal droplet 20 is directed to a surface of stage 60 to create the part (not shown). Optional additional energy source 70 can maintain or alter the temperature of stage 60 or the part or portions of the part, or both. Optional additional energy source 80 can maintain or alter the temperature of the droplet in flight or alter the temperature of stage 60 or part or portions of the part, or both.

As generally described, the methods and systems described herein can create a system to print dots, lines, planar patterns, or three-dimensional structures from drops of molten material created within a printing unit. The system can include the following components:
1. a material feed mechanism, receiving material from a supply unit and feeding it into the printing unit at a controlled rate.
2. a printing unit comprising
   a. a material heating mechanism that heats the material above the melting point
   b. a means of forming a stream of droplets, with one embodiment being the breakup of a moving molten material column into droplets by a surface tension mediated instability
3. a droplet trajectory modification mechanism that is used to direct the droplets to defined locations on a substrate
4. a print/support system around the above assembly such as a x-y-z table, motion control, vision system, sensors for temperature, drop position, substrate temperature, pattern/part temperature measurements, feedback controls to adjust droplet temperature and/or location based on sensor data, atmospheric control etc.
5. A method to form a pattern and/or object by printing material dots, lines, patterns or 3D structures by letting the molten material droplets impact onto a substrate or onto previously deposited material.

The material feed mechanism can take feed material from a supply, i.e, for instance by unwinding a wire from a spool. The material feed mechanism, optionally, can substantially straighten the wire to remove residual bending. The material feed mechanism, optionally, can pre-heat the feed material from the storage temperature to below the melting temperature of the material. The mechanism can feed the material “into” the heat source with high special precision, i.e. feed a wire through the center of a laser beam. The feed rate can be, for example, 0.1 to 50 meters per second, and may vary according to the wire material, diameter, and/or other considerations. The heat source can include a laser. The power of the laser can be between 10 and 50000 Watts, for example 80 to 500 Watts in one exemplary embodiment. The laser wavelength can be in the infrared or visible, for example 10.6 micron, 1064 nm, 532 nm or ˜450 nm; and ideally equal to the maximum absorption wavelength of the feed material.

Material feed can provide material either on demand (i.e. on/off, advancing material step wise at a constant or variable frequency), at variable speed, or at constant speed. The speed may be balanced to match the growth rate of the pattern or part.

The feed material can be any metal or alloy, provided the material may be liquefied by the energy source. The feed material, optionally, can also be a composite containing a metal/alloy and non-metallic particles, for example, a metal/alloy mixed with ceramic nanoparticles or microparticles or mixtures thereof. The feed material can have a defined cross-section geometry. The feed material can be amorphous or crystalline or a mixture thereof.

The cross-section geometry can be round (wire), rectangular (ribbon) or arbitrary shape (oval, rectangular with rounded edges, or other shape). The feed material cross section can be constant over the entire length of the feed material. Alternatively, the material cross section can change over the length of the feed material. The change can be a regular change or irregular change. For example, the feed material can be a wire with indentations at regular intervals.

In certain embodiments, the feed material can have a thickness across its diameter of about 1 to 10,000 microns, for example, less than 1,000 microns, less than 100 microns, or less than 50 microns. The molten droplets created from the feed material can have a size that is larger than, equal to, or smaller than the thickness of the feed material. In certain circumstances, the molten droplets can be monomodal distribution of sizes and substantially the same size. In other circumstances, the molten droplets can be a bimodal distribution of sizes, one distribution of sizes that is larger than the thickness of the feed material and another distribution of sizes that is smaller than the thickness of the feed material. The two size distributions can be separated during the execution of the method to deliver the larger distribution to one target and the smaller distribution to another target. The molten droplets can have a size of 500 microns, 300 microns, 200 microns, 150 microns, 100 microns, 50 microns, 20 microns, or 10 microns.

Another important parameter for the system and method described herein includes material heating and droplet formation. The literature describes many ways to make molten material droplets. These methods are generally based on a heated reservoir holding the molten material connected to a nozzle opening. In those methods, the reservoir is pressurized and a molten material stream exits the nozzle and breaks up into individual droplets due to Rayleigh-Plateau instability. Depending on the different embodiments, the pressure can be generated with a gas, an electromagnetic force, a vibrating piezo-element or a combination thereof several challenges exist with the current techniques: the reservoir and nozzle materials can oxidize or corrode in contract with the surrounding atmosphere or molten metal; the droplets all have the same temperature after ejection; molten materials are corrosive and impurities can leach from the reservoir materials into the molten material; and impurities or oxides inside and on the surface of the molten metal often lead to nozzle clogging and consequently reliability issues. There are also thermal management issues associated with maintaining a molten reservoir of high melting point materials.

The system and method described herein can have advantages over the previous methods. One approach under the system and method to generate molten material droplets is contactless, in which case the melt does not contact a surface. In other words, using the system and method described herein creates a situation in which no hot molten material comes into contact with any material other than the surrounding gas. The surrounding atmosphere can be ambient, inert, or it can be reducing to decrease contamination of the droplet through surface contact and/or oxidation of the molten droplet, or it can be reactive if desired to modify the characteristics of the droplet and/or the surface upon which printing is performed.

In certain circumstances, the material feeder can transport the material “into” a heat source that heats the material above the melting point. At low feed material velocities, the material can melt and a droplet of molten material hanging from the tip of the material can be formed due to surface tension forces balling up the molten material. At some point, for droplet diameters in the millimeter range, the molten drop will detach due to gravitational forces overcoming surface tension forces. When the feed velocity is low such that the molten material balls up, it is not possible to generate droplets with diameter of the same order as the wire diameter. Advantageously, by using the method described herein, the feed rate of the material is fast enough through the heat source such that a molten “column” or jet of liquid material is formed. The molten jet can remain stable for some time after exiting the heat source but will eventually break up into individual droplets due to Rayleigh-Plateau (RP) instability. The continuous section of the molten jet of wire must be at least as long as the wavelength of the fastest growing unstable mode, and this constrains the minimum required feed rate and thermal power. This wavelength defines the size of the droplets and is determined by the wire's surface tension, viscosity, and density. These material properties are a function of the wire's thermodynamic state, in particular the wire's temperature, and therefore the amount of heating also determines the droplet size. A schematic illustration is shown in FIG. 2A for a laser heating a wire. The superheating of the droplets (drop temperature minus melting temperature) can be adjusted by controlling the heat input into the droplet by the heat source. When using a heat source with variable thermal output, for example a laser, the temperature of each drop can be controlled individually. The individual droplets can be partially or fully molten.

Based on the material properties of metals such as platinum, gold, silver, copper, nickel, stainless steel and others, as well as anticipated wire sizes in the range of 5-500 microns, the required wire feed rates to achieve the described phenomenon will typically be between 50 and 1 m/s, respectively.

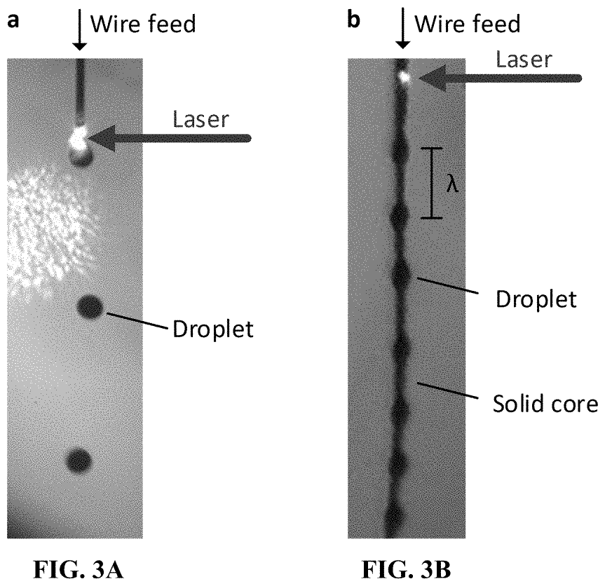

In one example, it was possible to demonstrate the continuous formation of ˜100 micron diameter platinum droplets from 50 micron diameter platinum wire in the lab using a laser beam as a heat source (exemplary embodiment). FIGS. 3A-3B show an example experiment for this case. For this experiment, a 50 micron platinum wire was fed at a speed of 2 m/s through a continuous-wave 1064 nm laser with a spot size of 40 micron and 327 W power. The experiment was captured with a high-speed camera recording at 50680 frames per second. The fundamental phenomenon is observed here: melting a sufficient length of the wire to generate a stable molten column which will then break up into individual droplets due to the Rayleigh-Plateau instability after a sufficient time. The region where the stable molten column was generated is shown via the two long dashed lines—note that this region remains stable throughout the duration of the experiment as the wire is continuously fed. Note also that the spatial wavelength of the instability (indicated with the shorter dashed lines as k) is approximately 9/R, where R is the radius of the wire, as is expected for the Rayleigh-Plateau phenomenon. Further, the wire feed rate of 2 m/s is approximately equal to what is expected to be required as a minimum feed rate for platinum wire of this size.

FIGS. 3A-3B depict a continuous droplet generation experiment. FIG. 3A shows that the laser power is sufficient to fully melt the wire, resulting in individual droplets. FIG. 3B shows that the laser power is insufficient to fully melt the wire, resulting in molten beads connected by a solid continuous an un-melted portion of the wire cross section, labeled as the solid core. Ribbed droplet breakup resulting from incomplete droplet separation from wire can be observed. Significantly larger wavelength and droplet diameter for the discrete droplets is observed as compared to the ribbed ones.

FIG. 3A depicts a set of sequential images taken from a high-speed camera showing the fundamental phenomenon showing breakup of the heated, moving wire into a stream of droplets for a 50 micron diameter platinum wire being fed at 2 m/s through a laser beam with a spot size of 40 micron and total power of 327 W. Specifically, frame (a) shows a frame just before laser is turned on. Frame (b) shows the wire once the laser is turned on, showing a visible hot spot on the wire surface, with a small heat-affected zone. Frame (c) shows the wire has traveled a significant distance such that a column of the wire with length much greater than the wire diameter has turned molten. The onset of the Rayleigh-Plateau instability can be seen in this frame. Frame (d) shows instability once it has become more pronounced. Frame (e) shows initial breakup of droplets due to instability. Frames (f) and (g) further show the breakup of individual droplets from the molten column generated by continuing to feed the wire through the laser beam.

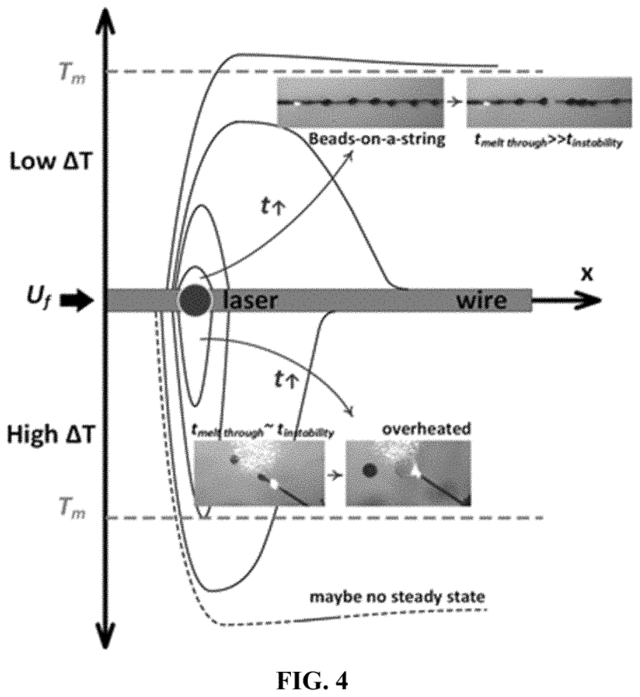

The expected phenomenon can also be validated by moving a laser at constant velocity over a stationary wire, instead of moving the wire through the laser beam. An example of an experiment for this case is shown in FIG. 3B. Here, a 25 micron diameter platinum wire was held stationary, and a 1064 nm continuous-wave laser with an 80 micron spot size and 70 W of power was scanned along the length of the wire at 4 m/s. The laser hits the wire from the right side, starting at the top and moving downward. FIG. 4 shows sequential images taken from the high-speed camera of the experiment. In this case, there is not enough power to fully melt through the wire, so it is not possible to observe individual droplet breakup. Rather, only part of the wire is melted, but we do see the Rayleigh-Plateau phenomenon—the molten material forms individual bumps on the surface of the wire, with the expected wavelength of approximately 9/R. Further the speed of the laser relative to the wire, at 4 m/s, is approximately as expected to be required for 25 micron platinum wire to break into droplets. From this experiment it is clear that if there were more power directed into the wire from a sufficiently high-powered laser, then the entire wire would melt through and individual droplet break could be observed.

FIG. 3B depicts sequential images taken from the high-speed camera for the case of a laser scanning along the length of a platinum wire. The wire is 25 micron, the laser has an 80 micron spot size and a power of 70 W, and is scanning at 4 m/s. Specifically, frame (a) shows the wire just before laser starts scan. Frame (b) shows when the laser scanning begins, and the onset of instability can just be seen. Frame (c) shows instability progresses and bumps start to grow. Frames (d)-(g) show instability progresses further and bumps form on the wire.

FIG. 4 depicts the influence of laser power, which affects a temperature gradient across the cross section of the wire; small temperature gradients result in incomplete melting, while large temperature gradients result in individual droplet generation. When laser intensity is not high, there is a low temperature gradient on the wire. It takes longer time to fully melt the wire (from the surface to the core) than for capillary instability to grow up. It will give the beads-on-a-string structure. Notably, temperature profile, either on the surface or at the core, is not uniform in downstream of the wire, so is the surface tension of the liquefied portion. Non-uniform bead speed and bead wavelength can be observed from high speed video analysis. When laser intensity is high, there is a high temperature gradient on the wire. For example, the first wire breakup (droplet formation) occurs within 1 or 2 wavelengths of capillary instability. Notably, this could happen before the temperature profile reaches the steady state. As a result, especially for the continuous laser heating, the temperature will keep rising and lead to wire overheating.

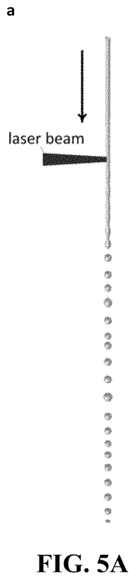

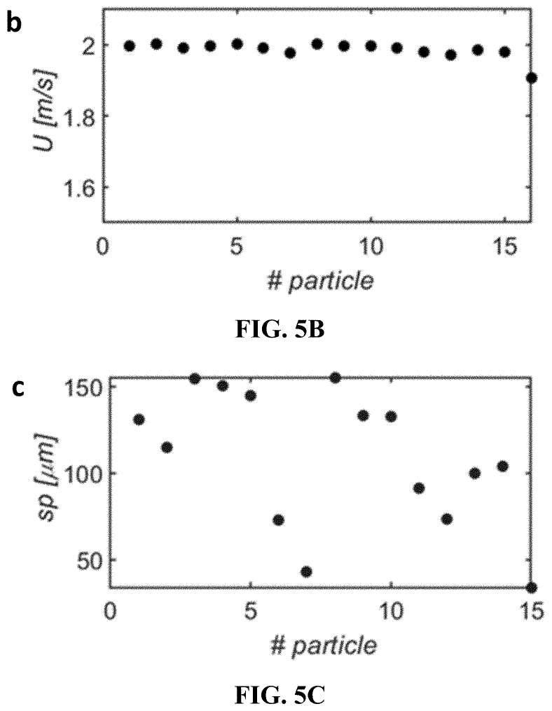

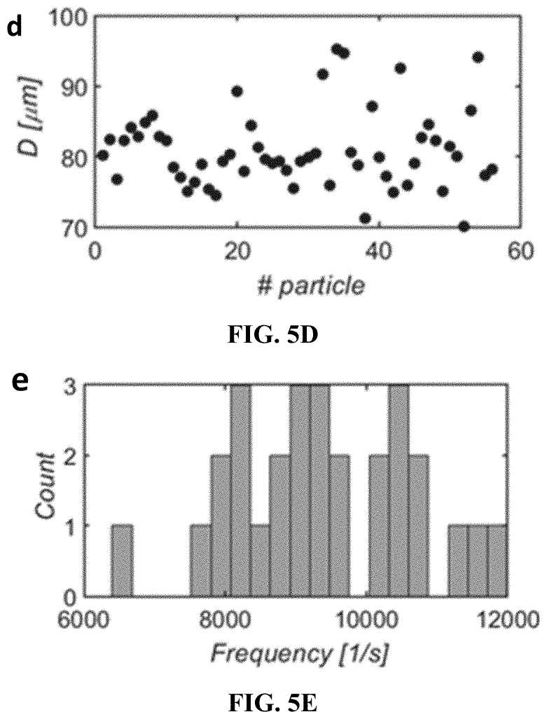

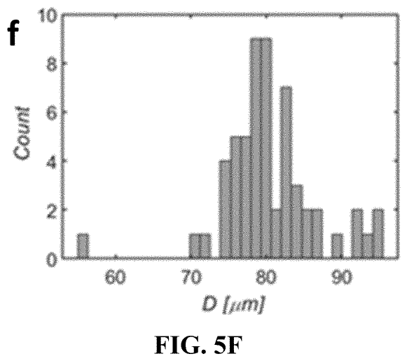

FIGS. 5A-5F show simulation results for droplet generation by constant laser power and wire speed. FIG. 5A depicts a simulation image with the following parameters: Wire feeding rate 2 m/s, Laser power 30 W (continuous), Laser spot size 50 um, Wire diameter 40 um. Wire material 304 stainless steel. FIG. 5B depicts the speed of each generated droplet. FIG. 5C shows spacing between two adjacent droplets along the axis line. The separated droplets show very similar velocities as wire feeding rate, there this non-uniform droplet spacing indicates non-uniform wire breakup. FIG. 5D shows the diameter of each generated droplet. FIG. 5E shows the print frequency of the generated droplets. FIG. 5F shows the diameter distribution of the generated droplets. Separated droplet size distribution shows a “dominant” diameter of ˜ 80 um, which is about two times of the initial wire diameter. Parametric optimization may not change the droplet diameter distribution significantly.

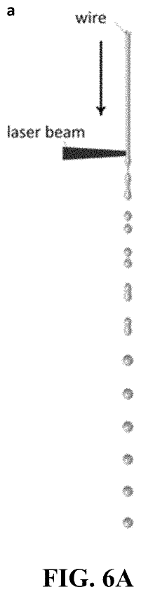

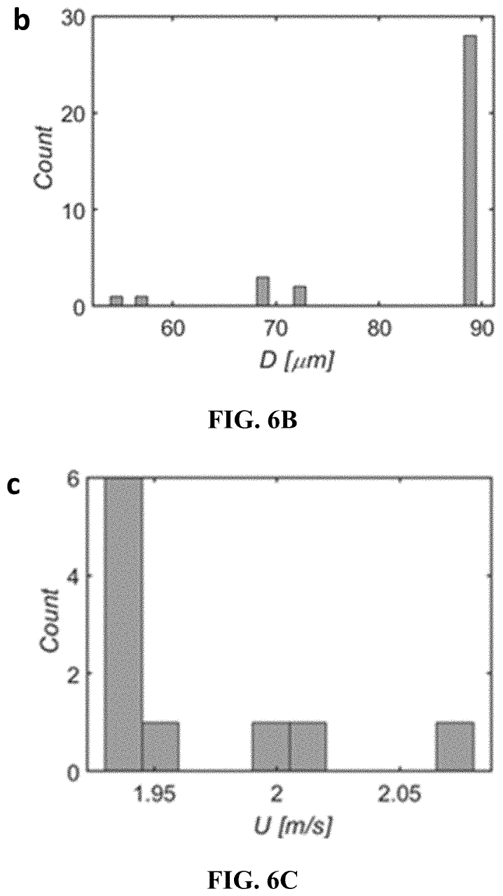

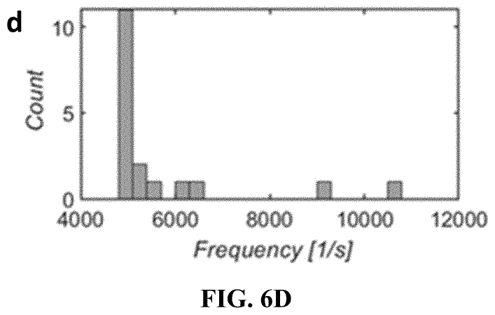

FIGS. 6A-6D depict simulation results for droplet generation by duty-cycled laser power and constant wire speed. FIG. 6A shows a simulation image based on the following parameters: Wire breakup with square wave pulsed laser heating (t=12 ms); parameters are 0.2 ms period, 0.5 duty cycle, 30 W power, 50 um spot size. FIG. 6B shows diameter distribution of the generated droplets. FIG. 6C shows speed distribution of the generated droplets. FIG. 6D shows print frequency of the generated droplets. Dominant droplet size is 89 um, which is close to continuous heating results in FIG. 5D, but showing less deviation. The pulsed laser heating case gives a bit slower droplets' speeds, but much more uniform droplet breakup, compared to FIGS. 5A-5E. FIG. 6D shows a dominant frequency around 5 kHz, and much less deviation than the case with continuous heating. This printing frequency can be controlled by modulating energy source, for example, pulsed laser setting

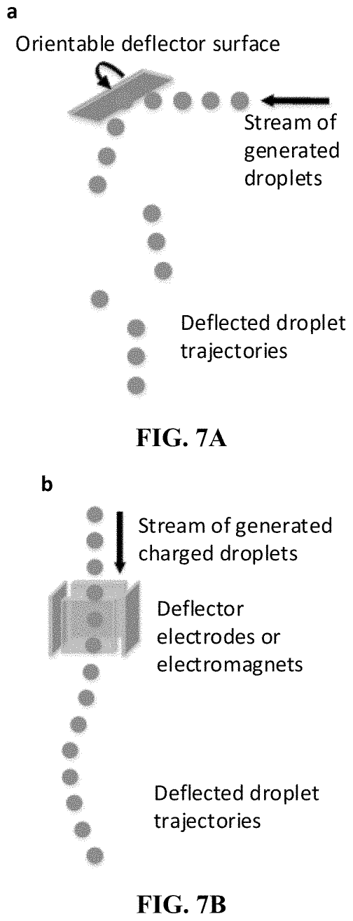

FIGS. 7A-7B depict conceptual embodiments of the deflector mechanism. FIG. 7A shows a stream of generated droplets bounce off an orientable deflector surface. FIG. 7B shows a stream of generated and electrically charged droplets passes through a controllable electric or magnetic field. In each example, the trajectory of each individual droplet may be modified.

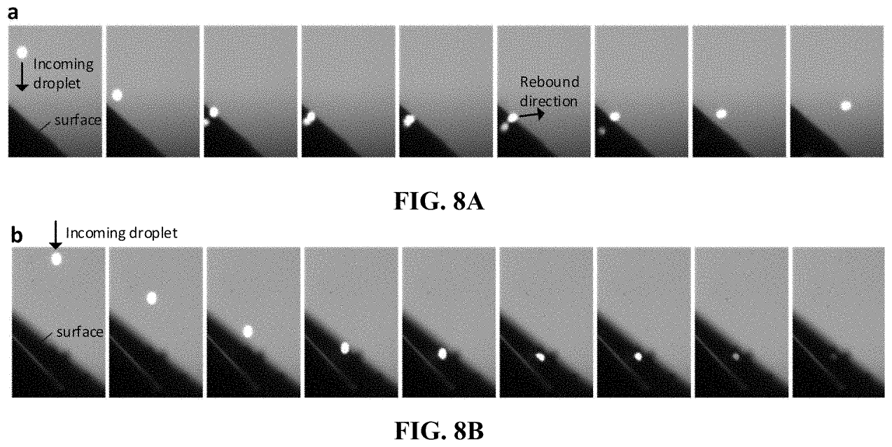

FIGS. 8A-8B depict a deflection surface experiment. FIG. 8A shows a molten metal droplet rebounds off a deflector surface comprising a micro-porous material imbibed with water. FIG. 8B shows a molten metal droplet sticks to the same micro-porous surface when imbibed with air.

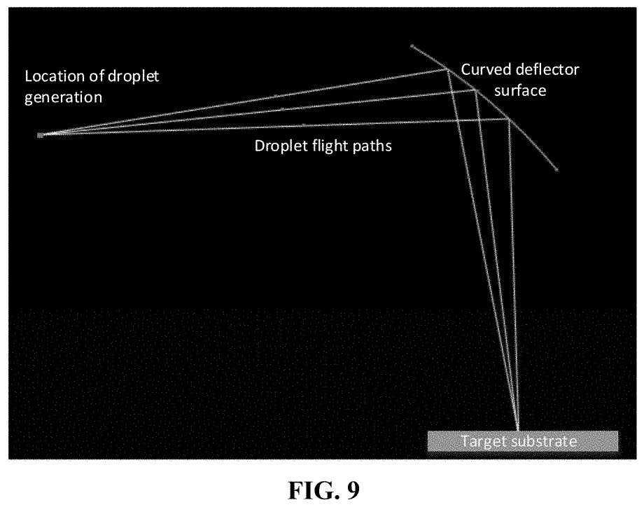

FIG. 9 shows flight paths of droplets deflected from a curved surface.

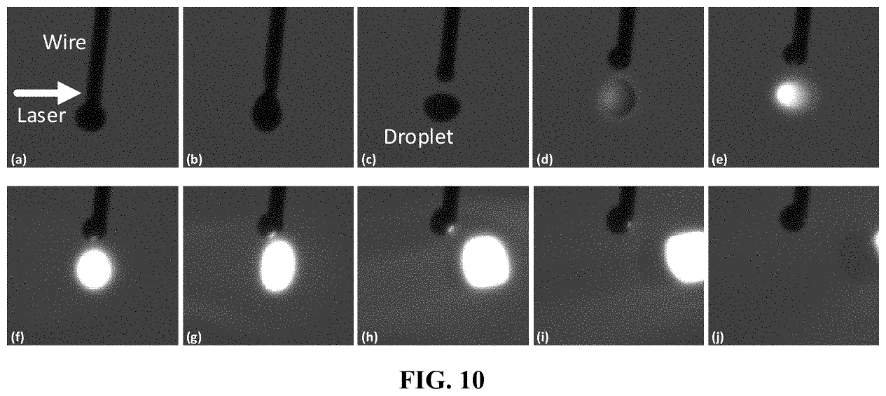

FIG. 10 depicts a discrete droplet generation experiment. The sequence of images (panels a-j) shows the end of a stationary wire heated with a laser to form a droplet. The laser continues to superheat the droplet, creating a vapor cloud that propels the droplet away from the wire.

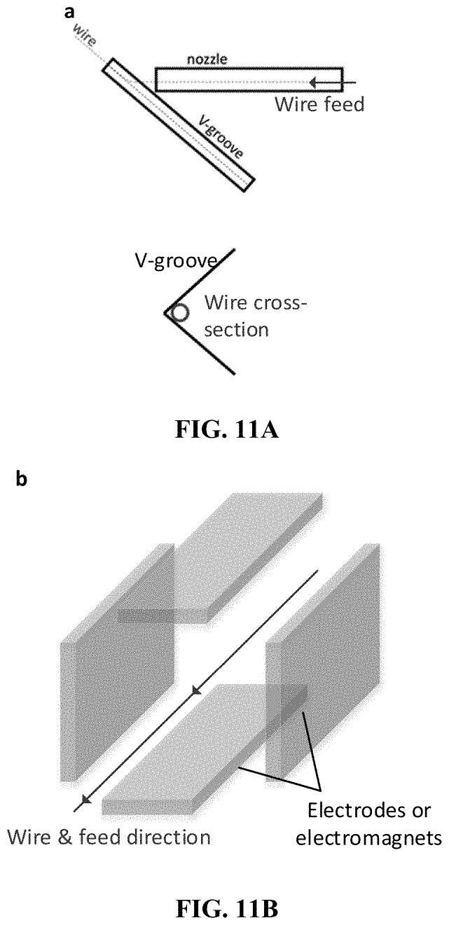

FIGS. 11A-11B depict embodiments of the wire alignment mechanism. FIG. 11A shows the wire is pushed against a v-groove by combination of bending stiffness and centripetal forces, such that the by two planar surfaces of a v-groove determine the alignment of the wire. FIG. 11A includes a view of the v-groove perpendicular to the end from which the wire extends. The wire exits the nozzle at a high speed, pinning it to the back of the v-groove and allowing the wire to be constrained to a linear path as it enters the laser beam. FIG. 11B shows a charged wire passes by a configuration of controllable electrodes or electromagnets, which impart a Lorentz force on the wire to control its alignment.

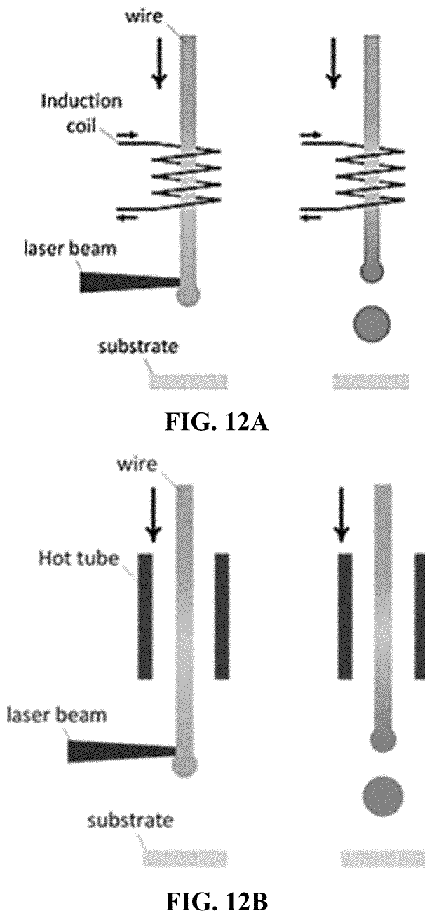

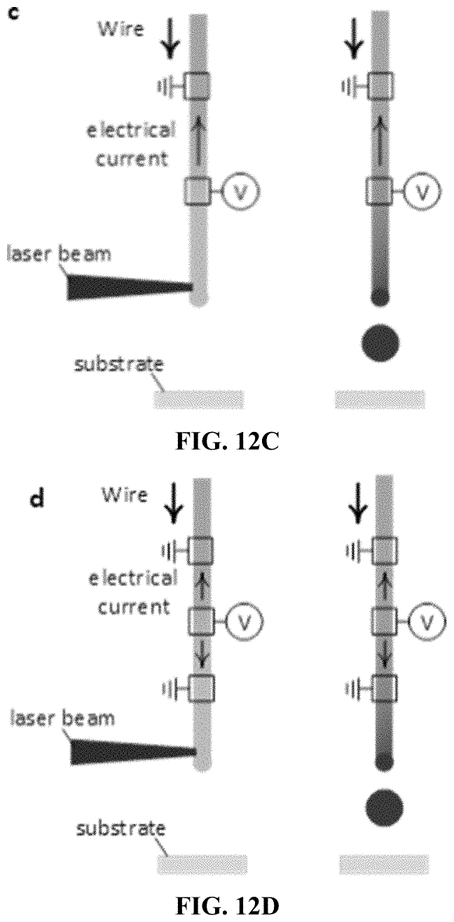

The wire can be preheated before it is fed into the laser melting region. FIGS. 12A-12D depict embodiments for preheating. FIG. 12A shows the wire passing through an induction coil. FIG. 12B shows the wire passing through a hot radiative tube. For macroscopic metal wires with mm-cm scale diameters, laser heating source may be not enough and cost-effective.
For both continuous laser melting and pulsed laser melting, the wire axial temperature gradient above wire's melting in the laser beam downstream region is more important than temperature in other regions. Therefore, one can preheat the melt wire in the laser upstream close to wire's melting point, and use laser heating to future melt the wire and modulate the liquified region's temperature gradient. FIG. 12C shows the wire being ohmically heated through contact at two locations held at different electrical potentials. Here, the generated droplets are charged, and the locations of contact with the wire may also serve to align it. FIG. 12D shows a wire contact configuration for ohmic heating and generation of uncharged droplets.

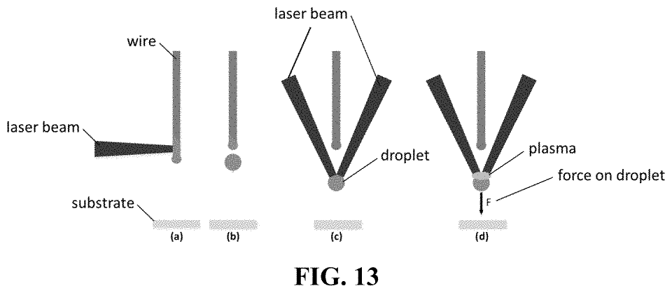

FIG. 13 depicts an example of droplet generation by a first laser, followed by vapor propulsion by a second laser.

FIGS. 14A-14B depict drawings of a wire-fed printhead and target substrate.

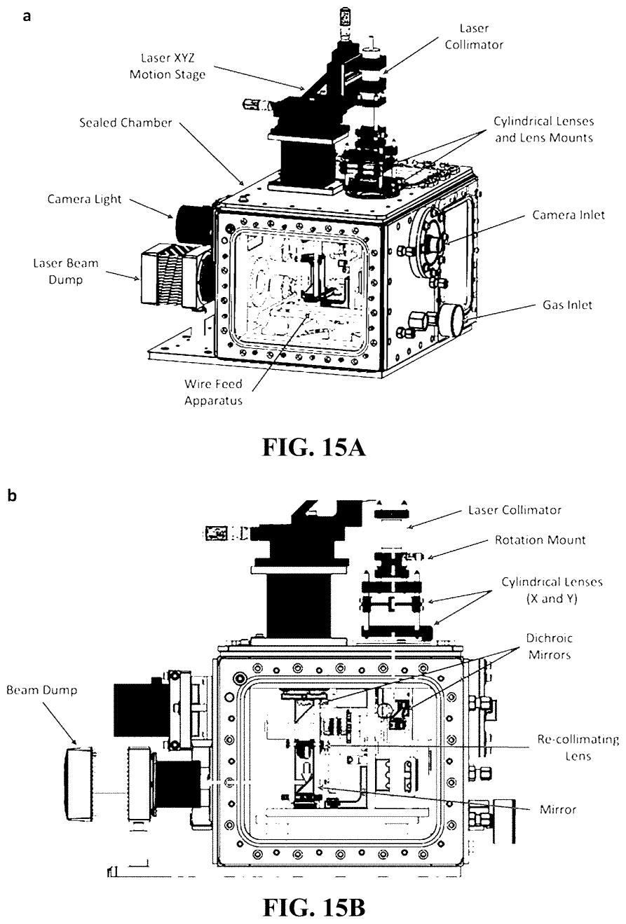

FIGS. 15A-15B show a system embodiment. FIG. 15A shows a full assembly with labeled components. The device includes a sealed chamber having a wire feed apparatus, a camera inlet, a camera light, a gas inlet, a laser collimator, a laser xyz motion stage, cylindrical lenses and lens mounts, and a laser beam dump. A high speed video camera can be aligned with the nozzle of the wire feed apparatus to capture the laser on the wire and subsequent droplet formation. The gas inlet (and outlet on the opposing side of the chamber, not shown) can allow a controlled atmosphere (for example, nitrogen gas) to be pumped into the sealed chamber, causing oxygen to be forced out. This can help prevent oxidation of the molten metal. An oxygen sensor can be placed in the outlet path to monitor the level of oxygen in the chamber. Nitrogen gas can be continuously passed through the chamber during use.

FIG. 15B shows a laser path and optical components; laser path shown, a wire feed nozzle is circled and indicates the focal plane of the laser. The device includes a laser collimator, rotation mount, cylindrical lenses (x and y), dichroic mirrors, a re-collimating lens, a mirror and a beam dump. The laser collimator, rotation mount, and lenses can be in all 3 translational directions (via the XYZ motion stage shown in FIG. 15A)—X and Y for alignment with the wire and Z for focusing onto the plane of the wire. The dichroic mirrors and the beam dump can be adjustable for alignment between the laser and the wire as well as between the laser and the beam dump. The cylindrical lenses can allow the focused laser to form a circle or elongated circle (ellipse). The rotation mount subsequently allows this ellipse to rotated and aligned with the wire. The dichroic mirrors can be used such that the light for the camera can pass through while the laser light is deflected.

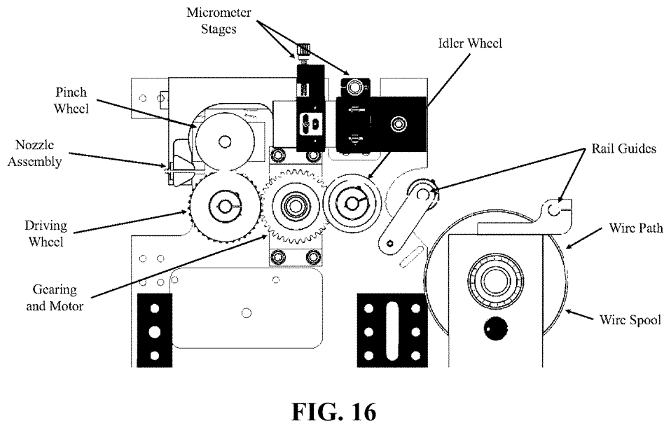

FIG. 16 shows components for wire feed machine, including wire path through the machine. The machine includes a wire spool, a wire path, a gearing and motor, a driving wheel, an idler wheel, micrometer stages, a pinch wheel, and a nozzle assembly. The spool of wire can be mounted to the base of the wire feeding apparatus and sits between two bearings to minimize rolling friction. Rail guides can serve to converge the wire from the long spool and to add tension to prevent slack from developing due to the freely spinning (non-driven) wire spool. Micrometer stages can control the position of the nozzle with respect to the wheels pushing the wire forward (allowing for alignment). The idler wheel can serve to converge the wire into a linear path (further convergence than the rail guides). The driving wheel can have a V-groove in which the wire sits and is driven by the motor. The pinch wheel can serve as a follower to the driving wheel and provide the nesting force (via compression springs) on the wire into the V-groove of the driving wheel. It can provide the traction for the wire to be pushed forward into the nozzle.

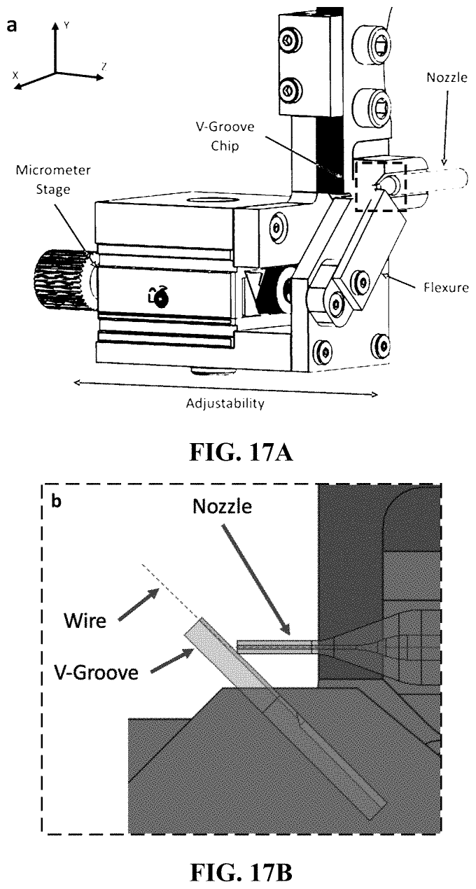

FIGS. 17A-17B depict a physical embodiment of v-groove wire alignment mechanism. FIG. 17B is an expanded view of the dotted region of FIG. 17A. The v-groove chip provides a constraint for the wire (FIG. 17A), located adjacent to the nozzle from which the wire is moving. The micrometer stage allows for adjustability of v-groove with respect to nozzle. Flexure provides normal force onto v-groove to keep it in place during machine operation. Flexure material and geometry is specified such that neither the flexure nor v-groove should fail.

The dynamical process of Rayleigh-Plateau breakup of the molten column may produce a sequence of uniform size droplets, or a repeating sequence of different size droplets depending on system parameters. For example, the breakup may produce a large main droplet followed by a smaller satellite droplet; these again may or may not coalesce during transit in the droplet stream. For the case where the droplets do not coalesce, the embodiment described here enables selection of which droplets are printed towards the substrate and which are captured within the print head. This enables, for instance, a “small droplet, high-resolution” mode and “large droplet, low-resolution” mode for the same printing unit and system parameters depending on which size droplet is captured.

Another important component of the system and method is the heat source. The energy source for providing the thermal input can be one of the following:
electromagnetic (e.g., a laser of any wavelength, preferably tuned to the absorption spectrum of the feed material, infrared source, radiative source, inductive source);
plasma
gas flame
electron beam;
resistive (joule) heating, i e., passing a current through the material;
conductive/diffusive heating through a gas; or
other heat sources.

In the system and methods described herein, there are several important additions to the above concepts that can be implemented. Examples include:
Modulating the heat source. The surface tension of molten metals depends on temperature and generally decreases with increasing temperature. Modulating the heat source creates a temperature variation along the axis of the material feed and consequently a varying surface tension on the surface that can be used to control the droplet break-up. By using a regularly repeating modulation over time, a more uniform droplet size distribution can be achieved compared to using a constant output heat source. By using a custom modulation pattern the droplet size can be controlled.
Controlling the heat input into each individual droplet by modifying the heat source intensity. The result will be a stream of liquid droplets where each droplet has a different temperature, and/or a different size. This is another key inventive step as it will improve bonding of the liquid droplet on the substrate after impact. Optionally a secondary heat source can be used to heat droplets individually in flight at an arbitrary location, independent of the droplet generation mechanism.

Additional properties/embodiments of the energy source(s) or stream break-up can include the following:
More than one energy source can be used to heat the material and/or droplets, successively or in parallel or both. For example, the material can be pre-heated to a temperature below melting point by one energy source and then heated above melting temperature by another energy source. In another embodiment the material can be molten by one energy source and the temperature of individual molten droplets can be controlled by another energy source.
The same energy source can be used multiple times. For example, a laser can be used to melt the material and to change the temperature of a droplet in flight, i e., by directing the laser, or one or more lasers with mirrors positioned using galvanometers, the material and droplet successively or simultaneously.
The energy sources can be spatially distributed, i.e., the material feed/droplets can be heated at any point between the material source and the deposited droplet, and heated for any duration of time during this transition;
The energy source can scan along the feed material in an intermittent way. For example, a material feed speed can be selected slower than the minimum needed for Rayleight-Plateau (RP) break-up. If a continuous heat source was used the feed material would simply ball up and form droplets with diameters many times that of the feed material. However, if the heat source is scanned along a short section of the feed material with a velocity equal or higher that that needed for RP breakup, the feed material in the heated section would break up into a series of small droplets as described above. The heat source can then be turned off for some time and the process can be repeated with another section of the feed material coming out of the material feeder.
Imaging/sensing can be used to determine the temperature of the feed material, and accordingly control the energy delivery;
Imaging/sensing can be used to determine the temperature of one or more droplets, and accordingly control the energy delivery during flight of the droplets;
An electric field can be applied in the vicinity of the stream, so as to further influence the breakup and flight of droplets;
The energy source can be constant or variable in space, time and intensity, i.e. controlling the intensity (position, time) of the energy source can be used to affect the dynamics of breakup, including but not limited to:
   starting/stopping the breakup
   modulating the size and frequency of droplet ejection
   controlling the temperature of the droplets including heating the droplets above the melting point by a desired margin
When the energy source is a laser, the following features can be important:
   a single beam can be directed at a wire from one side,
   multiple beams, either split from a single laser or from multiple lasers, can be directed at the wire from different sides,
   optics can be used to shape the laser beam can such that it issues a radially uniform intensity around the perimeter of the wire;
   any shape beam can be used: round, elliptical, substantially linear, rectangular, or other; and the intensity profile of the beam can be shaped to be gaussian, top-hat, or other
   a mirror assembly can be used to direct light that was reflected from the wire/feed material back onto the surface of the wire/feed material, i. e. to improve energy efficiency of the process or to reduce the laser power needed to melt the wire;
   the beam position can be controlled by mirror(s) which can be controlled by galvanometers;
   an annular laser beam concentric with the wire feed direction can be used
   the angle orientation of the laser beam with respect to the traverse direction of the wire may be acute, right or obtuse.

Another important parameter for the system and method described herein includes control of the temperature difference between the droplet and the substrate at the location of the droplet impact. If the temperature difference is too large, the droplet can bounce off the surface. If the temperature difference is too small, the bonding between the substrate and the droplet can be poor. The surface temperature of the substrate can vary in space and time during printing and, in order to obtain good adhesion, it is advantageous to control the temperature difference between the droplet and the substrate by adjusting the droplet temperature or substrate temperature or local substrate temperature or any combination thereof. The following features can be important:
the droplet and/or surface temperature can be controlled locally or globally or both to keep the difference between the droplet and part/substrate constant
the droplet and/or surface temperature can be controlled and the difference between the droplet and part/substrate during printing of the part can be adjusted for optimized adhesion, bonding, surface finish, porosity control, dimensional accuracy or other properties;
Imaging/sensing can be used to determine the temperature of the substrate, and accordingly control the energy delivery to the feed material and/or droplets in flight;
Imaging/sensing can be used to determine the temperature of certain portions of the substrate or the entire substrate or both, and accordingly control the energy delivery to the feed material and/or droplets in flight;
A laser can be used to deliver energy to the droplet and/or substrate;
Imaging/sensing can be used to determine temperatures of any part of the printer such as the droplet, environment, part, substrate, feed material etc. Any combination of temperature sensor data can be used to determine and control the energy delivery to any or all of the feed material, droplet, substrate and/or part. Exemplarily, a sensor can measure the droplet temperature after molten stream break-up and another sensor can measure the temperature of the part or substrate at the location of drop impingement. The sensor data can be used in a feedback control loop to determine the amount of energy needed for laser heating the droplet in flight and/or laser heating the part or substrate at the location or near the location of drop impingement.

Described above is a method to generate a stream of molten metal droplets by melting a wire with a heat source. In another configuration, instead of generating a continuous stream of molten droplets from a wire, a single droplet can be generated on demand from a wire. A schematic of the process is shown in FIG. 2B. A wire that is heated by a laser beam at a distance of approx. one wire diameter from the wire end will melt between the wire end and the remainder of the wire and the wire will split approximately at the location of the wire heating due to the Rayleigh-Plateau surface tension instability, forming a droplet. The newly formed droplet can have an inertia towards the remaining part of the wire and coalesce with the remaining wire.

By exerting an additional force on the droplet, the droplet can be prevented from coalescing with the remaining wire and it can be directed towards a substrate. FIG. 2B shows a schematic of this concept, where a force is exerted on the droplet after separation from the wire, accelerating it down to the substrate where it is deposited and eventually solidifies. In particular, FIG. 2B depicts drop-on-demand generation from the tip of a wire. Frame (a) shows the tip of the wire is heated with a laser beam to generate a molten column. Frame (b) shows the surface tension driven instability that causes a droplet to split off from the end of the wire, and a force is applied to the droplet to accelerate it towards the printing substrate. Frame (c) shows the droplet continues to move towards the substrate. Frames (d)-(e) show the droplet lands on the substrate and eventually solidifies.

There are many possible ways to exert a force on the droplet, some of which are described in more detail below (e.g., electrostatic, plasma shock wave, vapor propulsion, acoustic/acoustophoretic, drag, mechanical)—all of these methods are applicable for directing a single drop towards a substrate. For a proof of concept, we demonstrate using vapor propulsion via laser heating to exert a force on a detached droplet.

FIG. 10 shows images taken from an experiment where a molten droplet (approximately 50 micron diameter) is generated from a gold wire (approximately 25 micron diameter) and accelerated via vapor propulsion. The laser originates from the left. Frame (a) shows a solid wire before laser heating and melting—note the tip is bulbous from previous melting and droplet generation. Frame (b) shows laser melting has initiated, and the surface tension instability has begun to deform the molten material. Frame (c) shows droplet detachment occurs. Frames (d)-(e) show laser heating continues overheating the droplet, and a temperature difference across the particle becomes visible. Frames (f)-(g) show vapor is generated on the left surface of the droplet, and the pressure generated starts to accelerate the droplet to the right. Frames (h)-(j) show the droplet is accelerated further to the right. Note that overheating the droplet with the laser results in it appearing larger in the images due to optical effects of increased brightness from light emission at higher temperatures.

Initially, a sufficient length of the wire was melted such that surface tension causes an individual droplet to detach as previously described. The droplet was then initially traveling upwards with some momentum due to the dynamics of the detachment. The laser was then left powered on, such that the droplet continued to be heated to the point where some material started to be evaporated on the surface. The vapor generated created a pressure that then accelerated the droplet to the right. The same principle could be used to direct the droplet downward by irradiating the top of the droplet with a laser that comes down at an angle or is annular at the wire. Further the substrate could be positioned at any desired angle below or beside the wire to achieve the desired deposition. Additionally, while in this case the laser was on at a constant power for the duration of the experiment, the laser could also have an arbitrary power profile and/or a modulated intensity profile, for example initially having a relatively lower constant power to melt and detach the droplet, followed by a higher power pulse which is optimized to achieve the desired amount of vapor on the surface for proper acceleration and deposition, while minimizing the amount of vapor generated. A varying power profile could also be used to aid droplet detachment. Additionally to the laser having an arbitrary power profile or modulated intensity profile the laser can also be pulsed to generate the desired amount of vapor. The laser heating that is used for melting the tip, aiding droplet detachment, and generating vapor can all originate from the same laser or different lasers. Additionally to use the laser(s) to generate a vapor to exert a force on the droplet, the laser(s) can also be used to generate a plasma that can exert a force on the droplet and propel it towards the substrate, see also details below. As an example a continuous wave laser beam with or without modulation can be used to generate the droplet and a second pulsed beam can be used to generate a vapor cloud or plasma shock wave to propel the droplet towards the substrate.

Further detail is given below on different methods for modifying the trajectories of droplets, all of which can be applicable to the drop-on-demand case. However, it is valuable to clarify some of the possible configurations for the cases of electrostatic and mechanical force generation, as the configuration for the drop-on-demand case may be slightly different from the case of a continuous droplet stream. In particular, examples include
Electrostatic: the wire and the substrate can be held at different electric potentials, such that when the droplet detaches it will have some electric charge of the opposite potential compared to the substrate. An electrostatic force can thus be applied to the droplet to accelerate it towards the substrate. Alternatively, a separate electrode can be used instead of using the substrate as the electrode. Varying the pulse profile of the potential applied can be done to optimize the acceleration and trajectory of the droplet, and possibly to aid in droplet detachment. Operating in vacuum can be beneficial for higher fields to be used before electrical break-down between the wire and the substrate occurs.
Mechanical: the mechanical forcer, such as a reciprocating element like a ring that fits over the tip of the wire, and causes the droplet to detach when formed at the tip can move relative to the droplet so as to impart momentum on the droplet. The mechanical forcer could move back and forth on demand, could oscillate continuously, or could be attached to device that changes orientation of the deflection surface, for example, a rotating device that is rotated on demand or continuously and only intersects with the droplet during one part of the rotational trajectory. Alternatively, the wire and droplet can move relative to a mechanical surface, either translationally or rotationally.

The resulting droplet stream can be deposited directly onto a substrate by moving the stream in relation to the substrate, for example in a 3-axis or 5-axis system, described below.

Alternatively, when the wire translation speed required to match the droplet breakup frequency exceeds the motion capability of state-of-the-art motion stages (<<1-5 m/s), resulting in “pile up” of droplets, another mechanism can be used to manipulate the droplet trajectory that is not limited by the motion capability limitation. Such trajectory manipulations may be implemented in any case, regardless of the droplet speed emanating from the printing unit.

Several approaches for drop trajectory manipulation can be used to direct the molten droplets. The first approach can be electrostatic or magnetostatic manipulation. The material feed can be held at one potential and a charging electrode surrounding the material feed during Rayleigh-Plateau breakup can be held at another potential, resulting in a charged droplet after jet break-up. The flight path of the charged droplet can then be controlled by passing the droplet through an electrical field, i.e., between two charged plates, see FIG. 7B, showing a schematic of electrostatic droplet trajectory control. It can be important to reduce the influence of charged droplets with one another which can cause the droplets to diverge from the flight path of uncharged droplets. It can also be challenging to deflect a single droplet in the stream by a large margin from the mean stream path using this approach. Also, electrical breakdown of the ambient medium can limit the strength of the electrical field that may be applied, though improved performance may be obtained by operating in vacuum or other gas environments.

A second approach can include a plasma shock wave. For example, a laser beam with sufficiently high intensity impinging on a molten metal droplet can result in evaporation of material from the surface. Strong laser absorption in the vaporized material and plasma creation can result in a plasma shock wave that propels the droplet away from the origin of the shock wave. The existence of a plasma and/or plasma shock wave can propel the molten droplet in a controlled way towards a substrate. Using the plasma shockwave together with the droplet on demand generation can provide unique control of droplet generation and deposition. The process is shown schematically in FIG. 13. Referring to FIG. 13, the tip of a wire is irradiated by a laser beam and a droplet is formed. The droplet is further irradiated by a laser beam and a plasma is formed where the laser heats the droplet. The plasma rapidly expands and creates a force on the droplet, propelling it towards a substrate surface. The wire can be heated by a single laser beam, by multiple laser beams at the same or different locations and by multiple beams superimposed onto each other.

A third approach can include vapor propulsion. For example, a laser with sufficiently high intensity can impinge on a molten metal droplet, which, in turn, can generate vapor on the surface of the droplet that creates a pressure gradient and propels the droplet away from the impinging laser beam. In this circumstance, a force on the droplet can be created by evaporating material whereas for the plasma shock wave it is generated by rapidly expanding gas due to the plasma generation. The laser can be the same laser used to melt the material and generate the droplets, or it can be a different laser.

Another approach can include an acoustic or acoustophoretic approach. For example, a pressure wave in a gas surrounding a droplet can exert a force on a droplet that can be used to modify the droplet flight path.

Another approach can include a drag approach. For example, a gas stream flowing past a droplet can exert a force on a droplet that can be used to modify the droplet flight path and/or assist in detaching the droplet from the tip of the molten wire.

Another approach to trajectory control can include mechanical deflection. This can include mechanically deflecting the molten material droplet off a solid surface that can be located in the flight path, i.e., a form of mechanical mirror. This configuration is shown schematically in FIG. 7A. Referring to FIG. 7A, a droplet trajectory can be controlled by deflecting the droplet off a solid surface. The deflection approach can include a deflection plate and a control mechanism, for example, servo-control or a galvanometer rotary positioning mechanism. The droplet can be deflected by one or multiple deflector surfaces at one or multiple reflection angles.

Whether a liquid droplet bounces off a surface or sticks can be determined by many factors. Important factors include the wettability of the surface by the liquid (surface energies of liquid and solid), surface roughness, droplet temperature, surface temperature, thermal properties and stability of the impingement surface (i.e. melting/evaporation of the surface during impact, heat transfer between the particle and substrate during impact), surface impurities such as dust, surface oxides, adsorbed species etc., droplet size, droplet speed. Small molten metal droplets are often observed to bounce from a solid surface unless there is interfacial freezing (i.e., the droplet partially or completely solidifies while spreading) or the substrate melts under the spreading droplet or the droplets wets the surface well. It is, therefore, advantageous to use a material for the deflecting surface that has one or more or all of the below properties. The reflective material can have a higher melting point than the impinging droplet. The reflective material can be non-reactive to the atmosphere surrounding it and the molten impinging droplet. The reflective material can be substantially not wettable by the impinging droplet.

In this example, the deflection surface can be dense or porous. The deflection surface can be actively cooled or heated. It can also be advantageous to use a material with low thermal conductivity or thermal diffusivity to reduce cooling of the impinging metal droplet during contact.

In another embodiment of the deflection surface, an additional liquid at the deflector surface can be included. The liquid can be a continuous or discontinuous thin film on the surface, a liquid infused into or on top of a porous body forming the surface, channels filled with liquid in the surface or a combination thereof. The presence of the liquid can help prevent thermal damage to the surface and prevent sticking of the droplet to the surface. Examples of porous surfaces including porous ceramics (e.g., sintered or compacted powder, anodic aluminum oxide), porous metals (e. g., sintered or compacted powder), anodized metals (e.g., anodized aluminum), or carbon nanotube films (e.g., a ceramic-coated or uncoated carbon nanotube forest)

The concept was demonstrated by impinging molten platinum droplets onto a porous alumina substrate at an angle of ˜45 degrees. Ten molten Pt drops were deposited at various positions onto the dry material and all ten droplets were observed to stick to the surface. The substrate was then wetted with water and ten more droplets were deposited and all of them bounced off the wetted surface. FIGS. 8A and 8B show images taken from a high-speed camera during two of these experiments, one for the situation where the substrate is dry and the particle sticks (FIG. 8B), and one for the situation where the substrate is wet and the particle bounces (FIG. 8A). In each case, the droplet was molten platinum of approximately 100 microns in diameter, and the droplets were each traveling at approximately 1.4 m/s.

More specifically, in FIG. 8B, images of a molten 100 micron platinum droplet impinging on a dry porous alumina surface and sticking are shown. Frames (a)-(d) show a droplet falling towards surface. Frame (e) shows a droplet initially contacting the surface. Frames (f)-(i) show a droplet sticking to surface, deforming initially, then coming to rest and solidifying.

FIG. 8A shows images of a 100 micron platinum droplet impinging on a porous alumina surface filled with liquid and rebounding at approximately a 45 degree angle. Frames (a)-(c) show droplet falling towards surface. Frames (d)-(f) show droplet contacting the surface, deforming, recoiling and rebounding. Frames (g)-(j) show rebound of the droplet.

The images show melting of the surface when porous substrate is used as is. The contrasting surface image shows no melting of surface when pores are filled during droplet impact.

The surface roughness of the deflector surface can be adjusted from mirror finish to very rough. The porous structure can be made of a ceramic, metal, polymer or composite. The porous structure can also be made of fibrous nanostructures such as carbon nanotubes (CNTs), optionally coated with another material such as a ceramic (e.g., alumina). Such a surface can have low effective contact area with the impinging droplet, minimizing heat transfer, while being mechanically robust and porous, thus possibly improving supply of gas or liquid to the surface.

A thin vapor film between the droplet and the reflecting surface can be created by using a thermally unstable material for the reflecting surface that will decompose or pyrolyse during the impingement droplet, creating a vapor layer at the boundary.

In another embodiment the deflecting surface can be a single or multi-layer metallic or ceramic plate with cooling channels on the back side that can be actively cooled by circulating coolant through the cooling channels during droplet impingement. The structure can be a MEMS structure where the deflecting surface is a single or multi-layer thin metal or metal oxide film that can be supported by a silicon structure with etched cooling channels.

A deflector assembly can be constructed by using galvanometers similar to those used for guiding laser beams, here attaching a deflector surface rather than an optical mirror. This approach has several key advantages: the positioning of the mirror surface can be much faster than traditional motion stages and droplet stream velocities relative to a substrate, which can be greater than 10 m/s. The final droplet landing location can also be adjusted “digitally”, i.e. the drop landing pattern can be chosen arbitrarily for each droplet whereas electrostatic deflection results in a continuous “sweeping” pattern as described above. A deflector assembly can also be constructed by using a rotating polygon deflector surface. Moreover, the contour of the surface can be flat, or curved in a manner to refocus the droplets at a fixed distance after bouncing off the mirror (for example, a parabolic surface profile) in order to compensate for trajectory deviations of the droplet stream. The deflector surface can also be curved to allow particles with an angular variation from the ideal flight path to be focused back onto a single deposition spot, similar to a mirror focusing light. This concept is schematically shown in FIG. 9. Referring to FIG. 9, droplets originating from a droplet source with some angular variation can be deposited onto a single spot by “focusing” them with a curved deflector surface.

In certain circumstances, molten droplets experience cooling and will ultimately freeze while moving from the printing unit to the substrate. For very small droplets the travelled distance until freezing can be in the millimeter range. In one embodiment, the droplets can be deflected one or multiple times before freezing, partially or fully solidify during flight and then can be molten partially or fully again by an energy source such as a laser before impact on the substrate.

In another embodiment, liquid material droplets are generated and the distance between the molten droplet generator and the deflector surface is chosen to be large enough such that the droplets partially or completely solidify before being deflected. The particles can then be molten again in flight by an energy source, such as a laser beam, before impacting the build substrate. Optionally, multiple deflector surfaces can be used to deflect the solidified particles. Optionally, the particles can also be reflected one or multiple additional times between partially or fully solidifying and final deposition. Optionally, instead of re-melting the droplet, the substrate can be molten locally and the solid particle can be deposited into the meltpool on the surface of the substrate. Optionally, both the droplet and the surface can be heated or molten or both.

The deflector, optionally, may have an orientation that allows the droplets or particles to be reflected away from the substrate, thereby allowing selection of which droplets in the droplet stream are printed towards the substrate. A droplet or particle waste collection system can be implemented, or particles can be printed onto a waste area.

The overall print system can include of any of the above described components together with a 3-axis (x-y-z), 5-axis (x-y-z-a-b) or 6-axis (x-y-z-a-b-c) motion system for positioning the printing unit or the stage, or both, any number of control units, computers, vision systems (IR, visible, or UV, for example), sensors, or other components.

Examples of sensors can include any of photodiodes, pyrometers, IR/VIS/UV detectors, IR/VIS/UV cameras, X-ray detectors, ultrasonic detectors or mechanical force detectors. Multiple sensors can be used to detect the presence, velocity, velocity vector, temperature, diameter, volume, shape, circumference, outline, color, reflectance, emissivity, surface morphology, either momentarily or over time. The sensors can be arranged in a single or multiple locations.

In one example sensing the presence of a droplet can be performed by a light source illuminating the droplet in flight and a photodiode recording the intensity of the light source while the droplet passes through the beam of light. The reduction of the recorded light intensity, i. e. the shadow of the droplet, can be used to detect the presence of a droplet passing through the light beam. Additionally, a velocity of the droplet can be calculated from the intensity variation over time.

In another example, a high-speed camera, either in the infrared or visible spectrum, can be used to detect the location, velocity vector, shape or other properties as mentioned above of the droplet.

Using sensor data and optionally some physical models, i. e. for atmospheric drag or atmospheric cooling or radiative cooling, can be used to make predictions about the droplet flight path or temperature variation on the flight path. The data can further be used to, for example, modulate one or more power sources, to trigger other sensors or used in a feedback control loop.

The pressure inside the housing of the printer can be controlled to be at ambient pressure, higher than ambient pressure or lower than ambient pressure. Lowering the atmospheric pressure of the fluid that the droplets are travelling in can reduce drag forces and can reduce slowing down on the droplets in flight.

The atmosphere the molten droplets are exposed to can be controlled. The majority of liquid molten materials strongly react with oxygen and/or moisture in air and an atmospheric control chamber can be included to use vacuum, inert gas(es) or reducing gas(es).

Alternatively, the material feed stock may be housed within a reducing liquid. The high-speed motion of the material can entrain a fine viscous coating of the reducing liquid around the material as it transits through the printing unit and to the heat source, thereby preventing any reaction with oxygen and/or moisture in a standard room air atmosphere. Additionally, if the reducing liquid is capable of removing surface oxide formation from the surface of the material within a short amount of time or upon heating, then only a section of the traversing material needs to be coated before passing through the heat source, rather than storing the material stock in a reducing liquid.

The system can be a stand-alone unit or can be retrofit into an existing computer numerical control (CNC) machine or use it together with an existing 3D printer/additive manufacturing equipment, i.e., printing metal onto polymers or into metal parts being printed or manufactured by another method.

State-of-the-art powder-based 3D printing works by spreading a thin layer of powder, sintering/melting the powder with a scanning heat source such as a laser or electron beam and then repeating these steps to form a part inside the powder bed. The system and method described herein can be used to selectively add molten material droplets in any pattern to a powder bed process by either depositing molten droplets onto the freshly spread powder bed or onto the powder after passage of the heat source, either at a location with powder only or sintered or molten parts inside the powder bed. The powder can be a polymer, ceramic or metal and the molten material added can be any metal (same or different than the one used in the powder process). The droplet may optionally be allowed to solidify before impinging onto the powder bed, or upon impingement on the powder bed. The droplet, if molten when impinging, may infiltrate the powder bed.

The method to form a pattern or part (or other object) can use the system described above which can deposit individual droplets or particles, print patterns such as lines, grids, images, or arbitrary patterns as well as print three dimensional structures. In a generic print situation, the substrate might have a varying surface temperature both in x-y-z as well as over time due to in stationary heat transfer. Controlling the droplet temperature can be beneficial such that a specific difference between the droplet temperature and substrate temperature is maintained or the difference can be adjusted for each drop individually to manage heat input from the droplet into the substrate or part. Additionally, controlling the temperature between the droplet and the substrate can be beneficial to improve adhesion. The temperature difference between droplet and substrate can be chosen such that the thermal energy of the molten droplet can be sufficient to re-melt the substrate, resulting in good adhesion. An optimum temperature difference can be found to minimize the additional heat input into the substrate by additional heating and to maximize the adhesion between the droplet and the substrate.

In certain circumstances, multiple “printing units” can be used to increase the throughput of the system. Multiple printing units of different materials can be used to print multi-material parts or patterns, for example multiple wires of the same or different materials can be fed into the different printing units. The material jetting of multiple units can be actuated independently or in synchrony. Multiple printing units with different droplet sizes can be used to print parts with varying voxel sizes/local resolutions. In certain circumstances one laser can be used as heat source for multiple printing unit by splitting the laser into multiple beams or by switching the beam between multiple printing units.

Under certain circumstances, it can be challenging to deposit material at a high volumetric rate because heat cannot be conducted away from the printed part fast enough to ensure solidification before more material is deposited, resulting in distorted parts. In one example, one printing unit can print a thin closed perimeter of one material that always solidifies independent of the deposition rate and another printing unit can print a second material with lower melting point than the first material into the contour at high deposition volumes, forming a molten pool of the second material inside the perimeter of the solidified first material. The printed part can resemble a core-shell structure.

In another embodiment, any 3D printing technology (laser or ebeam powder bed fusion, direct energy deposit, binder jetting or similar) can be used to print a thin shell of a first material. A second material is then placed into the shell. The thermal properties of the second material are selected such that the shell does not melt upon filling with the second material. The second material can, for example, have a lower melting point than the first metal. The second material also can have the same or a slightly higher melting point than the first material and melting of the shell can then be prevented by natural or forced cooling of the surface of the shell. The second material can be cast into the shell or can be printed into the shell as liquid droplets. The second material can be molten or partially molten. The filling can occur during printing the shell, immediately after printing the shell while it is still hot or after cooling of the shell. The shell can optionally be re-heated before placing the second material into it. The shell can have one or multiple separate cavities. Multiple separate cavities can be filled with the same second material or with multiple different materials. The shell can have an arbitrary shape, can have different shapes or can contain intricate parts of printed material itself. The inside of the shell can be structured with features protruding from the surface that allow the shell to mechanically interlock with the material on the inside, for example when printing dissimilar materials that do not form a chemical bond between their surfaces.

In certain circumstances, the build stage, substrate or defined spots on the surface of the part can be heated. For example, heating the entire build stage, substrate, part, or combinations thereof, can be advantageous to reduce stress in the built part, i.e. the part can be kept at an elevated temperature during the entire 3D printing process and is then slowly cooled down after printing is finished. In one embodiment, the entire build volume, stage or part or only a fraction of the substrate, build stage or part are heated during the deposition process to temperatures of 0.1 to 0.99 times the melting temperature (in degrees Celsius) of the material to be deposited.

In another embodiment, a laser beam can be used to selectively heat a small portion of the substrate immediately before, during or after the impact of a single droplet to a temperature below or above the melting point of the material to be deposited. Heating a small area of the substrate approximately the size of the droplet at the impact location shortly before droplet impact is especially beneficial to enable good fusion of the impinging droplet with the substrate. For example, the droplet fuses with a small molten part of the substrate (liquid droplet impinging in liquid meltpool on the substrate surface) or part of the substrate can be re-melted by the impinging droplet, resulting in good metallurgical bonding. For example, one beam can be directed at the wire and one directed at the substrate. See FIG. 14A (second source not shown).

In certain circumstances, a laser beam can be used to selectively heat the droplet or an area surrounding the droplet or both after impact in order to control the cooling or solidification rate or both of the heat affected zone. Controlling the cooling and solidification times can be beneficial for controlling the microstructure or mechanical properties or both of the material, i. e. adjust grain size, grain orientation, diffusion of atoms in alloys, residual stresses or degree of crystallinity going from amorphous to fully crystalline.

In another example, a laser beam can be used to selectively planarize portions of or the entire surface of the printed part by momentarily heating a thin layer of the part to a temperature above the melting point, letting the molten thin film flow to even out roughness and letting the molten thin film cool below the solidification temperature.

In certain circumstances, support structures can be necessary to mechanically support parts to be build. When the support structures are monolithic to the part, significant time and effort is needed to remove these during post processing of the parts. In the present invention, the adhesion of a molten particle to the substrate can be controlled in the above mentioned process by adjusting the temperature difference between the impinging molten droplet and the substrate. If this temperature difference is chosen such that re-melting of the substrate occurs after droplet impact, the droplet adheres firmly to the substrate. If the temperature difference is chosen such that no re-melting of the substrate surface occurs, the solidified particle adheres poorly to the substrate. This behavior can be used to create single or multiple particle layers with low adhesion that can be inserted between support structures and the printed part to facilitate separation during post-processing.

Non-limiting examples of applications for the system and method are described below:
EUV light sources for future high resolution lithographic processes can work by jetting a stream of molten tin droplets into a vacuum chamber. The droplets can then be illuminated by a laser beam, creating a plasma plume and the plasma cloud emitting extreme UV light. The state-of-the-art droplet generator used in EUV systems can operate at a frequency of 50-80 kHz and emits tin droplets of 20-30 micron diameter. The system and method described herein can be used to generate a droplet stream of 20 micron droplets at rates up to 300 kHz using 10 micron diameter wire.
Anti-counterfeiting: high value parts from one manufacturer can theoretically be printed on any 3D printing machine and also be copied on any machine. Manufacturers are, therefore, looking for means to protect their parts against counterfeiting and one possibility can embed tiny particles of a high-density material into a 3D printed part during manufacturing, forming a pattern inside the part. The pattern can then be detected via x-ray, ultrasonic imaging etc. One application might be printing particles of high density materials such as gold, lead, Cu, stainless steel etc. into low density aluminum or titanium based aircraft parts. These types of patterns could also be used to uniquely mark/identify consumer electronics products, jewelry, watches, banknotes, medical packaging or other industries.
Marking: patterns of a printed material can be used to mark articles or create a unique pattern on the surface.
Jewelry/watches: the technology can be used to
   print decorative patterns onto rings, watches etc.
   3D print jewelry/watch components, e.g. rings, pendants, etc.
   Create multimaterial 3D printed jewelry, e.g., white and yellow gold intricate patterns that extend through the bulk or cladding of a stainless steel core with gold and/or platinum
3D printing of cooling structures for consumer electronics such as computers, mobile phones or for power electronics, also for non-uniform heat sources
For electrical connectors:
   Selective metallization of parts: contact pads for connectors or other parts that need to be soldered onto a PCB, e.g. EMI shields
   Metallic components inside connectors, e.g. for RF connectors
   Printing of metallic components directly into plastic connector parts
Contact-less wire bonding: forming a wire bridge with a metal such as Au between an semiconductor component and a rigid or flexible circuit board, e.g. for flexible hybrid electronics
Printing conductive lines/wires
   For EMI shielding in electronics products
   Printed conductive lines on flexible substrates
   Direct printing of metal lines onto non-conductive surfaces to replace wires, potentially replacing wire harnesses
   PCB manufacturing
   Print vias into PCBs during PCB manufacturing
   Solar cell metallization and interconnection
   Depositing metal lines from molten droplets onto previously printed Ag/Cu/etc. lines printed with micro or nanoparticulate inks by traditional printing technologies such as screen printing, flexographic printing, gravure printing etc.
Printing of magnetic materials for the manufacturing of, for example, motors
3D printing of engineering components
   potentially also with true multimaterial integration, i.e. printing stainless steel into copper or vice versa to improve the mechanical or electrical properties of the final part
   potentially printing gradient structures where the material composition gradually changes in one or more dimensions of the part
3D printing antennas or waveguides
   For telecom antennas
   3D antennas for electronics, such as cell phone antennas
   Embedding metallic antenna structures directly into plastic parts or onto non-conductive surfaces
3D printing passive electronics components or parts thereof
Tooling:
   Print near net-shape molds for e.g. injection molding
   Printing of drill bits, end mills, or other machine tools
Dental:
   3D printing of crowns, moldings etc. from e.g. CoCr, Au, Pt
Catalysis:
   Printing metals/precious metals in order to create precise catalytically active structures
   Printing a catalyst bed or body with a particular arrangement of materials (coatings, particle sizes/compositions, porosity etc.)
   Printing a catalyst substrate with tailored material properties (for example, porosity, wall thickness, surface structure, etc.) that serves as a backbone for later catalyst infiltration
Filtration: print filters with porous structures (homogeneous or graded), potentially including the housing
Soldering/brazing/welding: print molten solder droplets directly onto joints of parts to solder/braze/weld the parts while at the same time limiting heat input into the part
Medical:
   Printing high precision and miniaturized noble metal medical parts, i. e. radiopaque markers, either as separate part or directly onto medical equipment
   Printing surgical instruments
   Printing implants, potentially with fine porous surface

The system and method can be used to print droplets within the 1-5000 μm size range, and to print droplets in single (two dimensional) or multiple (three dimensional) layers with controlled arrangements. The system and method can be used to manufacture parts of various sizes, for example, parts from tens of microns in size, to hundreds of microns in size, to millimeters in size, to centimeters in size, to decameters in size, to meters in size. For example, the part can be 10-1000 microns, 1-10 millimeters, 1-10 centimeters, 1-10 decimeters, or 1-10 meters in size.

Other embodiments are within the scope of the following claims.

1. A method of generating individual molten droplets from a wire feedstock, comprising:
providing a feed material from a feed mechanism; and
directing an energy source at or near an end of the feed material to form a liquified region of the feed material into individual molten droplets.

2. The method of claim 1, further comprising feeding the feed material at a rate sufficient to break the liquified region into individual droplets.

3. The method of claim 1, further comprising generating a single droplet traveling with a trajectory away from the feed mechanism.

4. The method of claim 1, wherein sequentially produced molten droplets are selected to be uniform in size or different in size.

5. The method of claim 1, wherein sequentially produced molten droplets have a diameter that is larger than, equal to, or smaller than a diameter of the feed material.

6. The method of claim 1, further comprising altering the trajectory of individual molten droplets with a deflector.

7. The method of claim 6, wherein the deflector is near an end of the feed material.

8. The method of claim 6, wherein the deflector is an electric field, a magnetic field, a vapor propulsion wave or a plasma shock wave.

9. The method of claim 6, wherein the deflector includes a deflection surface.

10. The method of claim 9, further comprising controlling a temperature of the deflection surface.

11. The method of claim 9, wherein the deflection surface is flat or curved.

12. The method of claim 1, further comprising positioning droplets to impinge a target area of a substrate.

13. The method of claim 1, wherein the energy source includes one or more of the following: an electromagnetic source, a plasma source, an electron beam source, a joule heating source, an induction source, a convective source or a conductive source.

14. The method of claim 1, wherein the energy source includes a laser.

15. The method of claim 1, where the energy source is constant, modulated or pulsed or combinations thereof.

16. The method of claim 1, wherein the feed material is a wire or ribbon.

17. The method of claim 1, wherein the feed material includes a metal, a metal alloy, a plastic, a rubber, a ceramic, a composite or a glass.

18. The method of claim 17, wherein the feed material is a metal wire.

19. The method of claim 1, wherein the feed material includes Sc, Ti, V, Cr, Mn, Fe, Co, Ni, Cu, Zn, Y, Zr, Nb, Mo, Ru, Rh, Pd, Ag, Cd, Hf, Ta, W, Ir, Pt, Au, Al, Ga, In, Sn, Pb, As, Sb, Bi, or S.

20. The method of claim 1, further comprising guiding the feed material through an alignment mechanism immediately before directing the energy source to the end of the feed material.

21. The method of claim 1, wherein the molten droplets are generated in a controlled environment.

22. The method of claim 1, further comprising applying multiple energy sources to the moving feed material, so as to control the temperature of the feed material along its length and influence the formation of droplets.

23. A device comprising:
a feed mechanism that advances a feed material at a controlled speed or maintains a desired position of an end of the feed material;
an alignment mechanism that determines trajectory and position of the feed material; and
an energy source directed toward the end of the feed material to generate molten droplets.

24. The device of claim 23, further comprising a deflector to modify the trajectory of the molten droplets.

25. The device of claim 24, wherein the deflector includes trajectory modification by electric field deflection, magnetic field deflection, plasma shock wave deflection, vapor propulsion deflection, acoustic or acoustophoretic deflection, gas flow deflection, mechanical deflection, or a combination thereof.

26. The device of claim 22, wherein the energy source includes one or more of the following: an electromagnetic source, a plasma source, an electron beam source, a joule heating source, an induction source, a convective source or a conductive source.

27. The device of claim 23, further comprising a three, four, five or six axis control stage.

28. The device of claim 27, wherein the stage includes a temperature controller.

29. The device of claim 23, further comprising an atmospheric control chamber that allows the control of humidity, oxygen partial pressure, inert gas partial pressure, atmospheric pressure or reducing atmosphere in which the molten droplets are generated.

30. The device of claim 23, further comprising an optical sensor to determine the position or trajectory of the feed material or one or more of the molten droplets.

31. A method of fabricating a metallic feature on a surface comprising generating individual molten droplets according to the method of claim 1, wherein the molten droplets travel through a fluid medium after detaching from the feed material and prior to impacting the surface.

32. A method of forming a three-dimensional object comprising generating individual molten droplets according to the method of claim 1, wherein the molten droplets travel through a fluid medium after detaching from the feed material and prior to impacting a surface to form a portion of the three-dimensional object.
